(19) United States
(12) Patent Application Publication
(10) Pub. No.: US 2023/0141594 A1
(43) Pub. Date: May 11, 2023

(54) THERMAL LASER EVAPORATION SYSTEM AND METHOD OF PROVIDING A THERMAL LASER BEAM AT A SOURCE

(71) Applicant: MAX-PLANCK-GESELLSCHAFT ZUR FÖRDERUNG DER WISSENSCHAFTEN E.V., München (DE)

(72) Inventor: Wolfgang Braun, Bietigheim-Bissingen (DE)

(21) Appl. No.: 17/916,155

(22) PCT Filed: Apr. 9, 2020
(86) PCT No.: PCT/EP2020/060152

§ 371 Date: Sep. 30, 2022

(51) Int. Cl. C23C 14/28; B23K 26/06; B23K 26/067; B23K 26/12; B23K 26/352; B23K 26/362; G02B 27/09; G02B 27/10

(52) U.S. Cl. CPC C23C 14/28; B23K 26/067; B23K 26/127; B23K 26/352; B23K 26/362; B23K 26/0648; B23K 26/1224; G02B 27/106; G02B 27/0905; G02B 27/0911; G02B 27/0988

(57) ABSTRACT

The present invention is related to a thermal laser evaporation system (10), the thermal laser evaporation system (10) comprising:
a laser light source (30) for providing a thermal laser beam (34) for evaporating one or more materials (22) from a source (20);
a thermal laser beam shaping system (40) comprising a collimation lens (42) and a focusing lens (44) for directing the thermal laser beam (34) onto the source (20);
a vacuum chamber (12);
a vacuum window (14) for conducting the thermal laser beam (34) into the vacuum chamber (12); and
an aperture (16) arranged within the vacuum chamber (12) between the vacuum window (14) and the source (20).

Further, the present invention is related to a method of providing a thermal laser beam (34) at a source (20) in order to evaporate one or more materials (22) from the source (20); the method comprising the steps of:
providing a thermal laser beam (34);
directing the thermal laser beam (34) via a thermal laser beam shaping system (40) comprising a collimation lens (42), a shaping device (60) and a focusing lens (44) into a vacuum chamber (12) comprising a vacuum window (12) for conducting the thermal laser beam (34) into the vacuum chamber (12) and through an aperture (16) arranged within the vacuum chamber (12) at the source (20).

The present invention is related to a thermal laser evaporation system, the thermal laser evaporation system comprising a laser light source for providing a thermal laser beam for evaporating one or more materials from a source, a thermal laser beam shaping system comprising a collimation lens and a focusing lens for directing the thermal laser beam onto the source, a vacuum chamber, a vacuum window for conducting the thermal laser beam into the vacuum chamber and an aperture arranged within the vacuum chamber between the vacuum window and the source. Further, the present invention is related to a method of providing a thermal laser beam at a source in order to evaporate one or more materials from the source. The method according to the invention comprises the steps of:
providing a thermal laser beam;
directing the thermal laser beam via a thermal laser beam shaping system comprising a collimation lens, a shaping device and a focusing lens into a vacuum chamber comprising a vacuum window for conducting the thermal laser beam into the vacuum chamber and through an aperture arranged within the vacuum chamber at the source.

In thermal laser evaporation systems, a laser light is normally directed at a certain angle onto a source material arranged within a vacuum chamber. To achieve a stable evaporation rate, the beam either needs to be scanned across the surface of a larger source, or the source size, laser power and beam size need to be matched such that the source material on average is uniformly evaporated across the top surface of the source.

To meet these constraints, the beam size and/or position on the source may be varied by moving the laser beam, together with its shielding aperture, along its propagation axis, with constant focal length and divergence. To scan the beam over an individual source, the laser beam and shielding aperture may be moved either along the two directions in the surface plane of the source, or, with the appropriate corrections, in the plane of the shielding aperture.

However, these methods are not very practical, as they require the precise collective movement of components inside and outside the vacuum chamber, thereby increasing the complexity and decreasing the reliability and versatility of the whole apparatus. This affects in particular the possible range of synthesis conditions and geometries that may be used.

In view of the above, it is an object of the present invention to provide an improved thermal laser evaporation system and an improved method of providing a thermal laser beam at a source which do not have the aforementioned drawbacks of the state of the art. In particular it is an object of the present invention to provide a thermal laser evaporation system and a method which allow a control of parameters of the laser beam at the source in high accuracy in an especially easy and cost-efficient way.

This object is satisfied by the respective independent patent claim. In particular, this object is satisfied by a thermal laser evaporation system according to claim 1 and by a method of providing a thermal laser beam at a source according to claim 15. The dependent claims describe preferred embodiments of the invention. Details and advantages described with respect to a thermal laser evaporation system according to the first aspect of the invention also refer to a method for depositing source material on a target material according to the second aspect of the invention and vice versa, if of technical sense.

According to a first aspect of the invention, the object is satisfied by a thermal laser evaporation system, the thermal laser evaporation system comprising:
a laser light source for providing a thermal laser beam for evaporating one or more materials from a source;
a thermal laser beam shaping system comprising a collimation lens and a focusing lens for directing the thermal laser beam onto the source;
a vacuum chamber;
a vacuum window for conducting the thermal laser beam into the vacuum chamber; and
an aperture arranged within the vacuum chamber between the vacuum window and the source,
wherein the thermal laser beam shaping system comprises a shaping device arranged in between the collimation lens and the focusing lens for adapting at least one of a position, a shape, and a size of the thermal laser beam at the source.

A thermal laser evaporation system according to the invention can be used for a thermal evaporation and/or sublimation of one or more source materials, in particular for a deposition onto a target material. A wide variety of source materials is possible, in particular metals and all other solids. However, with special source holders also liquid and gaseous source materials can be used. The source, arranged in a suitable source holder and/or constructed in a self-supporting manner, is arranged within a vacuum chamber.

According to the invention, the vacuum chamber can be used to contain a vacuum, for instance as low as 10⁻¹¹ mbar, and/or any suitable reaction atmosphere with a pressure between 10⁻¹¹ mbar and 1 mbar. Such a reaction atmosphere can for example contain molecular oxygen, ozone, molecular nitrogen or other reaction gases.

An external laser light source provides the thermal laser beam. Laser light forming the laser beam can be provided over a wide range of energies, preferably starting with IR light up to UV light. In particular, for different source materials, an accordingly adapted laser light can be chosen.

According to the invention, a thermal laser particularly is adapted to evaporate and/or sublimate the source material by continuously or at least essential continuously impinging on the source at an angle between 0° and 90°, preferably between 30° and 60°, and heating the source with a laser energy below the energy necessary to create a plasma.

The laser light enters the vacuum chamber through the vacuum window and impinges onto the source, passing the aperture on its way through the vacuum chamber. Preferably, the aperture extends perpendicular to the optical axis of the thermal laser beam. This allows shielding the vacuum window from a deposition of the evaporated and/or sublimated source material.

In most of the cases, the laser source provides the thermal laser light as an at least partly diverging beam, in particular if the last element of the laser source is an optical fiber. Amongst other things, the thermal laser beam shaping system of the thermal evaporation system according to the invention provides a compensation of this divergence of the laser beam provided by the laser source. As basic elements, the laser beam shaping system comprises a collimation lens and a focusing lens.

The collimation lens preferably transfers the diverging laser beam provided by the laser source into a parallel or at least essentially parallel laser beam. In most of the embodiments of the laser beam shaping system, the collimation lens forms the first element of the laser beam shaping system along the laser beam. At the other end of the laser beam shaping system, the focusing lens is arranged. It receives the parallel or at least essentially parallel laser beam and directs it onto the target. Preferably, a focal volume, in which the laser beam reaches its minimal extent, is located within the vacuum chamber between the vacuum window and the source. Additionally and equally preferred, the aperture can be placed at and around, respectively, this focal volume.

It is essential for the present invention that a shaping device is arranged in between the collimation lens and the focusing lens in order to vary the parameters of the laser beam at the source present within the vacuum chamber from the outside. The shaping device comprises elements for modifying the laser beam and hence as a result at least one of a position, a shape, and a size of the thermal laser beam at the source can be influenced and adapted. In other words, a wide variety of parameters of the laser beam actually impinging on the source can be adapted.

By altering the parameters, such as position, of the thermal laser beam on the source, the location on the source where the evaporation and/or sublimation takes place can be selected, in particular actively selected.

By adapting the shape of the laser beam, distortions caused by the projection of the impinging laser beam onto the source can be compensated. In addition, sources of any shapes, in particular also non-rotational symmetric shapes, can be uniformly illuminated. Additionally, also a non-uniformly illumination of the surface of the source is possible, for instance for a compensation of a non-uniform heat dissipation and/or a source with areas containing different materials.

An adaptation of the size, in particular a compression and/or expansion of the laser beam, influences the spatial energy density of the laser on the source. This allows for instance an adaptation for different source materials comprising different melting and evaporation temperatures.

As the shaping device is arranged in a section of the laser beam in which the laser beam preferably is parallel or at least essential parallel, these adaptations can be provided in an especially simple manner.

In addition, the thermal laser beam shaping system is completely arranged outside of the vacuum chamber. Any impact of the beam shaping system on the reaction atmosphere within the vacuum chamber, for instance caused by movable elements of the beam shaping system and in particular of the shaping device, can be avoided. Also a deposition of evaporated and/or sublimated material of the source onto parts of the laser beam shaping system is impossible.

Further, the thermal laser evaporation system according to the invention can be characterized in that the shaping device preserves a parallel or at least essential parallel alignment of the thermal laser beam after the collimation lens. In this preferred embodiment of the laser evaporation system according to the invention, the collimation lens and the focusing lens are constructed adapted to each other in that the collimation lens transfers the incoming divergent laser beam provided by the laser light source into a parallel laser light beam. Subsequently, the focusing lens receives the parallel laser light beam and directs the laser light onto the target.

Due to optical properties, the focusing lens directs all incoming light onto the target, as long as it impinges onto the focusing lens in a parallel beam. Hence, by preserving the parallel or at least essentially parallel alignment of the thermal laser beam after the collimation lens by the shaping device, the adaptions and/or alterations of the laser beam provided by the shaping device have no impact on the directing functionality of the focusing lens. In other words, the laser light beam adapted by the shaping device is directed by the focusing lens onto the source without need for additional compensation. In particular, a focal volume, in which the focusing lens focuses the laser beam, also stays stationary at the same place within the vacuum chamber. Preferably, the aperture can be positioned with its aperture opening at this focal volume, hence also the aperture can stay stationary independent of any adjustments of the laser beam provided by the shaping device.

In addition, the thermal laser evaporation system according to the invention can comprise that the collimation lens and the focusing lens are stationary within the laser beam shaping system, in particular within the thermal laser evaporation system with respect to the source and the laser light source. In other words, the outer ends of the laser beam shaping device remain fixed, independent of the status of the shaping device within the laser beam shaping system. This allows to arrange and to fix the laser beam shaping device with respect for instance to the vacuum chamber and/or the laser light source. In particular optical alignments of the whole thermal laser evaporation system can be preserved, even if the laser light beam is altered by the laser beam shaping system.

In an additional embodiment, the thermal laser evaporation system according to the invention can be characterized in that the shaping device comprises at least some of the following components selected from the group of members consisting of one or more mirrors, one or more beam compressors, one or more beam expanders, one or more beam splitters, one or more lenses, one or more prisms and combinations of the foregoing. This list is not terminated so that also other suitable optical components can be used as part of the shaping device. In summary, a wide variety of laser beam altering possibilities can be provided by the shaping device by choosing the suitable optical components.

Further, the thermal laser evaporation system according to the invention can comprise that the shaping device comprises one of the following shape adapting elements for adapting the shape of the thermal laser beam:
Anamorphic prism pairs
Combinations of cylindrical lenses
Beam clipping elements
Free-form mirrors

This list is also not terminated so that also other suitable shape adapting elements can be used as part of the shaping device. The shape adapting elements allow to actively alter the shape of the laser beam. For instance, beam clipping elements can shadow parts of the laser beam. The other optical elements mentioned in the list actually deform the laser beam, for instance to alter a laser beam with a circular cross section into a laser beam with an elliptical cross section. Free-form mirrors can be used to replace any of the mentioned optical elements like prisms or lenses.

Additionally or alternatively, the thermal laser evaporation system according to the invention can be characterized in that the shaping device comprises one of the following size adapting elements for adapting the size of the thermal laser beam:
A defocusing lens and a matched focusing lens
A focusing lens and a matched defocusing lens
Beam clipping elements
Beam compressors
Beam expanders
Free-form mirrors

This list is also not terminated so that also other suitable size adapting elements can be used as part of the shaping device. The size adapting elements allow to actively alter the size of the laser beam, in particular the size of a cross section of the laser beam perpendicular to its optical axis. For instance, beam clipping elements can shadow parts of the laser beam and hence reducing its size. A pair of a defocusing lens and focusing lenses can, depending on their order along the laser beam, enlarge or shrink the size of the cross section of the laser beam as well as beam compressors and beam expanders. Again, free-form mirrors can be used to replace any of the mentioned optical elements like prisms or lenses.

According to an additional or alternative embodiment of the thermal laser evaporation system according to the invention, the shaping device comprises one of the following position adapting elements for adapting the position of the thermal laser beam on the source:
Prisms
Mirrors, in particular free-form mirrors
Diffractive optical elements
Beam clipping elements

This list is also not terminated so that also other suitable position adapting elements can be used as part of the shaping device. The position adapting elements allow to actively altering the position of the laser beam, in particular the position of the laser beam perpendicular to the optical axis of the laser beam before the position adapting element. Clipping elements shadow parts of the laser beam and hence shift the center of gravity of the remaining laser beam. The other optical elements are able to actively alter the position of the laser beam and hence to provide a position adaption without loss of laser beam energy.

Additionally, the thermal laser evaporation system can be improved by that the thermal laser beam shaping system comprises a driving apparatus for moving at least one of the position adapting elements for scanning the source by adapting the position of the thermal laser beam on the source. By moving at least one of the position adapting elements, also the position of the laser beam on the source moves accordingly. In other words, the surface of the source can be scanned by the positions of the thermal laser beam provided by the laser beam shaping system. An especially even time averaged distribution of the energy of the thermal laser beam onto the whole surface of the source and as a result an especially uniform temperature distribution within the source near to its illuminated surface can be provided.

Further, the thermal laser evaporation system according to the invention can be characterized in that the thermal laser beam shaping system further comprises a splitting device for splitting the thermal laser beam coming from the laser light source into two or more partial laser beams, wherein the shaping device is configured to adapt at least one of a position, a shape, and a size of the two or more partial laser beams. In other words, after passing the laser beam shaping system, two or more separate laser beams are provided and can be used to evaporate and/or sublimate source material at accordingly two or more positions.

In particular, on these two or more positions, different sources can be arranged to allow a simultaneous evaporation and/or sublimation of two or more different source materials. As the shaping device is able to adapt at least one of a position, a shape, and a size of the two or more partial laser beams, all advantages provided by the shaping device described above can be provided for each of the partial laser beams. Preferably, within the laser beam shaping system, along the laser beam the splitting device is placed before the shaping device.

In an improved embodiment of the thermal laser evaporation system according to the invention, the splitting device comprises one of the following splitting elements for splitting the thermal laser beam coming from the laser light source into two or more partial laser beams:
Mirrors, in particular free-form mirrors
Prisms
Apertures

This list is also not terminated so that also other suitable splitting elements can be used as part of the splitting device. Preferably, also these splitting elements, and hence the splitting device as a whole, preserves a parallel alignment of the laser beam after the collimation lens. Hence, each of the two or more partial laser beams is treated by the shaping device similar to the unsplit laser beam provided by the laser source.

Preferably, the thermal laser evaporation system according to the invention is improved by that the shaping device is configured to adapt the two or more partial laser beams differently with respect to at least one of a position, a shape, and a size of the two or more partial laser beams. In other words, each of the two or more partial laser beams can be altered with respect to position and/or shape and/or size independently with respect to the remaining partial laser beams. Therefore, flexibility with respect to the parameters of the provided partial laser beams can be improved.

Further, the thermal laser evaporation system according to the invention can comprise that the thermal laser beam is impinging onto the source at an angle between 30° and 60°, in particular at an angle of 45°, so that an elliptical beam spot adjusted by the laser beam shaping system directed at the source produces a circular beam spot on the source. The preferred impinging angle of 45° renders possible to provide enough arranging space for both the source and the target. However, a circular laser beam impinging at an angle, preferably of about 45°, onto a source results in an elliptical footprint of the laser beam on the source. By providing an elliptical beam spot, perpendicular to the optical axis of the laser beam, this can be compensated and a circular beam spot at source location can be provided. This is especially of advantage for sources with a circular cross section, as a complete and even illumination of these sources can be provided.

According to a further embodiment of the thermal laser evaporation system according to the invention, the collimation lens and/or the focusing lens is integrated into the shaping device, in particular that the collimation lens forms an upstream end of the shaping device and/or the focusing lens forms a downstream end of the shaping device. An especially compact embodiment of a laser beam shaping system can thereby be provided.

Additionally, the thermal laser evaporation system according to the invention can be characterized in that the focusing lens focuses the thermal laser beam on a pointlike focal volume located in the vacuum chamber between the vacuum window and the source, and wherein the aperture comprises an aperture opening and is arranged with its aperture opening at the focal volume for shielding the vacuum window from particles evaporated from the source.

The pointlike focal volume represents the smallest extent of the laser beam. By arranging the aperture with its aperture opening around this focal volume, an optimized shielding of the vacuum window against deposition of evaporated and/or sublimated source material can be provided. In particular, in a further embodiment, the aperture opening is even created by pointing the laser beam with its pointlike focal volume onto the aperture. An especially precise alignment of laser beam and aperture can thereby be achieved.

According to a second aspect of the invention, the object is satisfied by a method of providing a thermal laser beam at a source in order to evaporate one or more materials from the source; the method comprising the steps of:
providing a thermal laser beam;
directing the thermal laser beam via a thermal laser beam shaping system comprising a collimation lens, a shaping device and a focusing lens into a vacuum chamber comprising a vacuum window for conducting the thermal laser beam into the vacuum chamber and through an aperture arranged within the vacuum chamber at the source, wherein the step of directing the thermal laser beam via the thermal laser beam shaping system comprises a configuration of at least one of a position, a shape, and a size of the thermal laser beam at the source by the shaping device.

The method according to the invention can be implemented in a thermal laser evaporation system, in particular for evaporating and/or sublimating at least one material of a source placed in a vacuum chamber of the thermal laser evaporation system.

In a first step of the method according to the invention a thermal laser beam is provided, preferably by a laser light source. For instance, the laser light source can comprise an optical fiber to guide the laser light to the vicinity of the vacuum chamber.

In the following step of the method according to the invention, the laser light is directed into the vacuum chamber onto the source. For this purpose, the vacuum chamber comprises a vacuum window. Within the vacuum chamber and between the vacuum window and the source, an aperture is arranged for shielding the vacuum window against material evaporated and/or sublimated from the source.

Especially, outside of the vacuum chamber, a laser beam shaping system is arranged for conducting the thermal laser beam through the vacuum window into the vacuum chamber. This laser beam shaping system comprises at first a collimation lens for a compensation of a divergence of the thermal laser beam provided by the laser light source, for instance after leaving the aforementioned optical fiber. At the opposed end, the laser beam shaping system comprises a focusing lens to focus, project and direct the thermal laser beam through the vacuum window and the aperture onto the source.

In between the collimator lens and the focusing lens, a shaping device is arranged. During carrying out the method according to the invention, this shaping device provides a configuration of at least one of a position, a shape, and a size of the thermal laser beam at the source.

By altering the position of the thermal laser beam on the source, the location on the source where the evaporation and/or sublimation takes place can be chosen, in particular actively chosen. By adapting the shape of the laser beam, distortions caused by the projection of the impinging laser beam onto the source can be compensated. In addition, sources of any shapes, in particular also non-rotational symmetric shapes, can be uniformly illuminated.

An adaptation of the size, in particular a compression and/or expansion of the laser beam, influences the spatial energy density of the laser on the source. This allows for instance an adaptation for different source materials comprising different melting and evaporation temperatures. In other words, by implementing the method according to the invention, these crucial parameters of the laser beam at the target can be addressed and actively adapted.

Preferably, the method according to the invention can be improved by that the method is carried out by a thermal laser evaporation system according to the first aspect of the invention. All features and advantages described above with respect to a thermal laser evaporation system according to the first aspect of the invention can hence also be provided by a method according to the second aspect of the invention carried out by a system according to the first aspect of the invention.

Further, the method according to the invention can be characterized in that a parallel or at least essential parallel alignment of the thermal laser beam after the collimation lens is preserved by the shaping device. In this preferred embodiment of the method according to the invention, a collimation lens transferring the incoming divergent laser beam provided by the laser light source into a parallel laser light beam and, subsequently, a focusing lens directing this parallel laser light beam onto the target are used.

Due to optical properties, the focusing lens directs all incoming light onto the target, as long as it impinges onto the focusing lens in a parallel beam. In particular, a focal volume, in which the focusing lens focuses the laser beam, also stays stationary at the same place within the vacuum chamber. Preferably, the aperture can be positioned with its aperture opening at this focal volume, hence also the aperture can stay stationary independent of any adjustments of the laser beam provided by the shaping device.

Hence, by preserving the parallel or at least essential parallel alignment of the thermal laser beam after the collimation lens by the shaping device, the adaptions and/or alterations of the laser beam provided by the shaping device have no impact on the directing functionality of the focusing lens, in particular on the positon and/or size of a focal volume on which the focusing lens focuses the laser beam. In other words, the laser light beam adapted by the shaping device is directed by the focusing lens onto the source without need for additional compensation.

Additionally, the method according to the invention can comprise that the shape of the thermal laser beam is adapted by clipping parts of the thermal laser beam and/or by using anamorphic prism pairs and/or a combination of cylindrical lenses and/or free-form mirrors for altering the shape of the thermal laser beam. By clipping or actively altering the shape of the thermal laser beam, the area on the source impinged by the thermal laser beam can be specified. Hence it is possible to adapt the shape of the impinging laser beam to a shape of the source and/or to intentionally illuminate only parts of the surface.

Preferably the method according to the invention can be improved by that a thermal laser beam provided by the laser light source with circular cross section is transformed by the shaping device into a thermal laser beam with an elliptical cross section. This special embodiment of the method according to the invention allows in particular to completely illuminating a source with a circular cross section by a thermal laser beam impinging on the source with an angle, for instance 45°. In other words, the elliptical shape of the impinging laser beam can be chosen such that after impinging on the source, the circular cross section of the source is matched.

Further, the method according to the invention can be characterized in that the size of the thermal laser beam is adapted by clipping parts of the thermal laser beam and/or by using a matched pair of a defocusing lens and a focusing lens and/or beam compressors and/or beam expanders and/or free-form mirrors. By actively adapting and/or altering the size of the laser beam, the area of the source illuminated by the laser beam can be adapted.

In particular, also outshining of the source by the impinging laser beam can be prohibited. Additionally, the size of the laser beam can be chosen such that the laser beam illuminates only a part of the source. In particular, especially when the laser beam is compressed or expanded to alter the size of the laser beam, also an energy density of the laser beam can be adjusted.

In another embodiment the method according to the invention can comprise that the position of the thermal laser beam on the source is adapted by clipping parts of the thermal laser beam and/or by using position adapting elements, in particular mirrors and/or prisms and/or diffractive optical elements, for altering the position of the thermal laser beam within the beam shaping system, in particular with respect to an optical axis of the thermal laser beam provided by the laser light source.

Altering a position of the thermal laser beam allows actively choosing the part of the source to be illuminated. For instance, the source can be internally divided in four quadrants and each quadrant comprises a different source material. In this example, actively altering the position of the thermal laser beam provides the possibility to choose the source material to be evaporated and/or sublimated. Additionally or alternatively, also a single material source can be illuminated at different positions, for instance to prevent uneven wear of the source.

According to a preferred embodiment of the method according to the invention, adapting the position of the thermal laser beam includes scanning the source by moving at least one of the position adapting elements by a driving apparatus of the thermal laser beam shaping system. Scanning the surface area of the source spreads the energy deposited onto the source. A local overconsumption of the source can thereby be prohibited. By moving at least one of the position adapting elements, this scanning can be provided especially easily.

Further, the method according to the invention can be characterized in that the step of directing the thermal laser beam via the thermal laser beam shaping system comprises splitting the thermal laser beam coming from the laser light source into two or more partial laser beams by a splitting device of the thermal laser beam shaping system. This splitting allows using the same laser light source to simultaneously illuminate two or more different positions of the source, wherein at these different positions also different materials can be located. Preferably, the shaping device adapts at least one of a position, a shape, and a size of the two or more partial laser beams, especially independent of each other.

Additionally, in another embodiment of the method according to the invention, the thermal laser beam shaping system focuses the thermal laser beam on a pointlike focal volume located in the vacuum chamber between the vacuum window and the source, and wherein an aperture is arranged with its aperture opening at the focal volume and shields the vacuum window from particles evaporated from the source.

The pointlike focal volume represents the smallest extent of the laser beam. By positioning this focal volume between the source and the vacuum window, an unintentional focusing of the thermal laser beam onto a wall of the vacuum chamber when missing the source can be prohibited. Further, by arranging the aperture with its aperture opening around this focal volume, an optimized shielding of the vacuum window against deposition of evaporated and/or sublimated source material can be provided. In particular, in a further embodiment, the aperture opening is even created by pointing the laser beam with its pointlike focal volume onto the aperture. An especially precise alignment of laser beam and aperture can thereby be achieved.

The present invention is further described hereinafter with reference to illustrated embodiments shown in the accompanying drawings. There is shown:

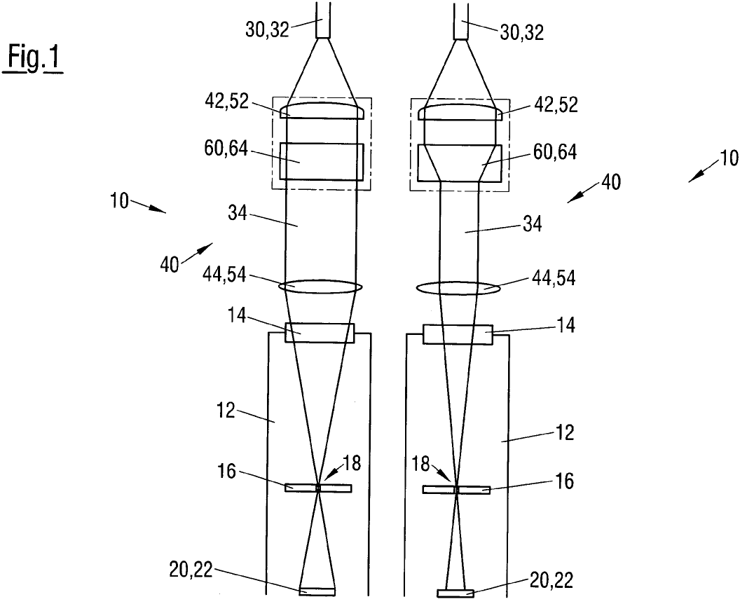

FIG. 1 A thermal laser evaporation system according to the invention with a thermal laser beam shaping system altering a size of the laser beam,

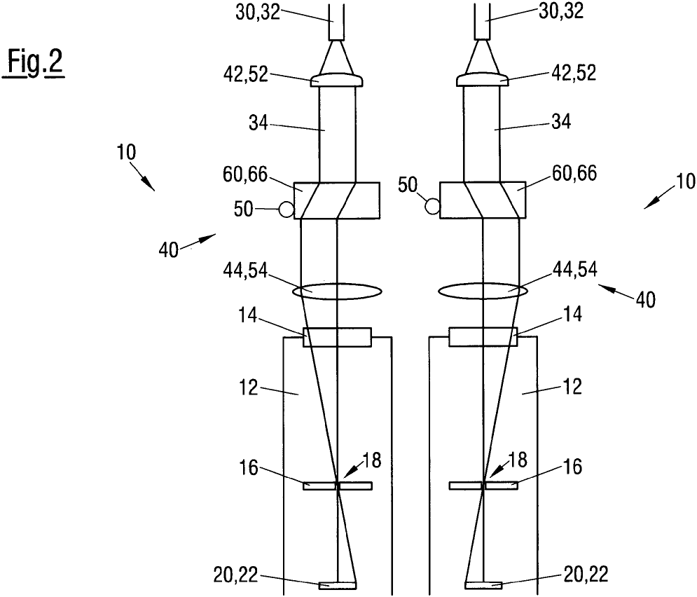

FIG. 2 A thermal laser evaporation system according to the invention with a thermal laser beam shaping system altering a position of the laser beam,

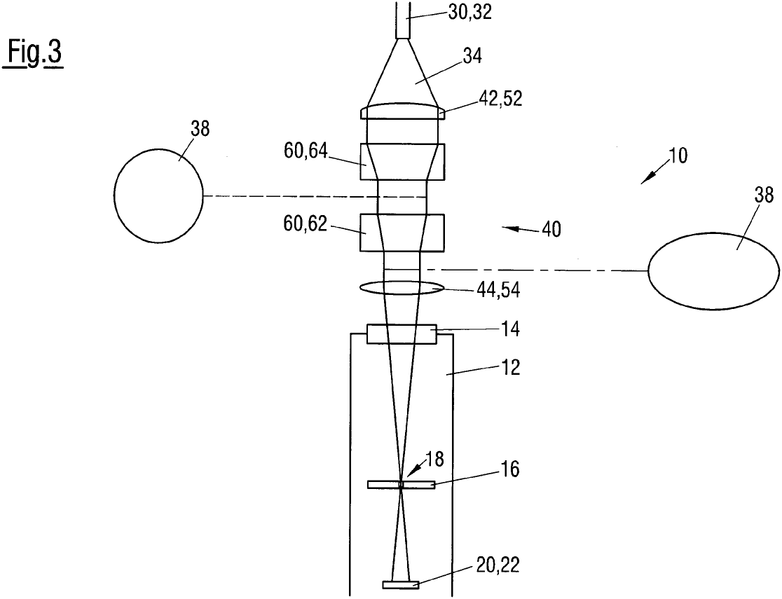

FIG. 3 A thermal laser evaporation system according to the invention with a thermal laser beam shaping system altering a size and a shape of the laser beam, and

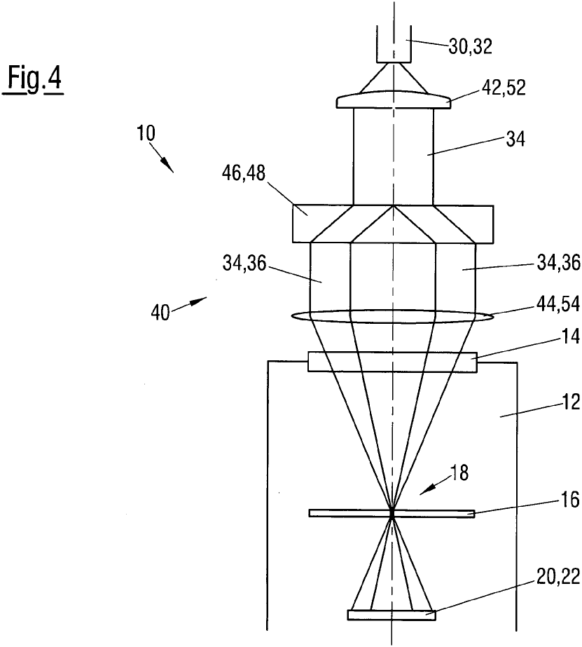

FIG. 4 A thermal laser evaporation system according to the invention with a thermal laser beam shaping system splitting the laser beam in two partial laser beams.

All FIGS. 1 to 4 show different embodiments of a thermal laser evaporation system 10 according to the invention. Accordingly, in the following the common parts of the laser evaporation systems 10 depicted in FIGS. 1 to 4 are described together, whereby the differences of the embodiments are pointed out.

The depicted thermal laser evaporation systems 10 comprise a laser light source 30, whereby in all embodiments the terminal end of an optical fiber 32 is shown. The laser beam 34 is directed by a laser beam shaping system 40 onto a source 20 placed within a vacuum chamber 12.

The source 20 provides the material 22 to be evaporated and/or sublimated by the impinging laser beam 34. The laser beam 34 enters the vacuum chamber 12 through a vacuum window 14.

The laser beam shaping system 40 focus the laser beam 34 onto a pointlike focal volume located within the vacuum chamber 12 between the vacuum window 14 and the source 20. At and around this focal volume, an aperture 16 is arranged, whereby an aperture opening 18 of the aperture is aligned with respect to the pointlike focal volume of the laser beam 34. The aperture provides shielding the vacuum window 14 from a deposition of evaporated and/or sublimated material 22 of the source 20.

The depicted embodiments of the laser evaporation system 10 essentially differ in their laser beam shaping systems 40. Hence, in the following, these laser beam shaping systems 40 and their functionalities are described.

All depicted laser beam shaping systems 40 share a collimation lens 42 at an upstream end 52 of the laser beam shaping system 40 and a focusing lens 44 at the respective downstream end 54 of the laser beam shaping system 40. In this connection it should be noted that the upstream end 52 is located closest to the laser light source 30 and the downstream end 54 is located furthest away from the laser light source 30.

At least an additional shaping device 60 (see FIGS. 1 to 3) or an additional splitting device 46 (see FIG. 4) is arranged in between the collimation lens 42 and the focusing lens 44. The laser beam 34 emerging from the optical fiber 32 is divergent in most of the cases. The collimation lens 42 is adapted to this convergence and transfers the incoming laser beam 34 into a parallel aligned laser beam 34. The focusing lens 44 receives this parallel aligned laser beam 34 and directs it onto the source 20, in particular including the focusing onto the aforementioned pointlike focal volume arranged within the vacuum chamber 12.

As depicted, the shaping devices 60 and also the splitting device 46 depicted in FIG. 4, preserve the parallel alignment of the laser beam 34. Hence, the alterations and adaptations of the laser beam 34 provided by the shaping devices 60 and by the splitting device 46, have no impact onto the general optical imaging properties of the laser beam shaping device 40 determined by the collimation lens 42 and the focusing lens 44. In addition, this allows arranging these elements stationary, the collimation lens 42 and the focusing lens 44, within the laser beam shaping system 40 and in particular with respect to the end of the optical fiber 32 and the source 20.

In FIG. 1, an embodiment of a laser beam shaping device 40 is shown, in which a switchable size adapting element 64 forms the shaping device 60 of the laser beam shaping system 40. Such size adapting elements 64 are for instance beam compressors, beam expanders, free-form mirrors and/or matched pairs of defocusing lenses and focusing lenses. In particular, in the status depicted on the left, the size adapting element 64 is deactivated and essential no size alteration of the laser beam 34 is present. On contrast to that, on the right hand side of FIG. 1, the size adapting element 64 is activated and the laser beam 34 is compressed. This for instance increases a spatial energy density of the laser beam 34 on the target 20.

Additionally and as depicted by the slash-dotted lines, in this embodiment of the thermal laser evaporation system 10, the collimator lens 42 is integrated into the shaping device 60. An especially compact setup can therefore be provided.

Also FIG. 2 shows two embodiments of the thermal laser evaporation system 10 according to the invention. In contrast to FIG. 1, the shaping devices 60 are constructed as position adapting elements 66. Such position adapting elements 66 can be constructed for instance by using prisms, mirrors, diffractive optical elements and/or beam clipping elements.

As described above, the shaping devices 60 have no impact onto the general optical imaging properties of the laser beam shaping device 40 determined by the collimation lens 42 and the focusing lens 44. Hence the position alteration of the laser beam 34 provided by the position adapting elements 66 are directed by the focusing lens 44 onto the source 20, resulting in different impingement areas on the source 20.

Additionally, a driving apparatus 50 is mechanically connected to the position adapting element 66 to induce a movement of the respective position adapting element 66. This allows to actively alter and choose the impingement area of the laser beam 34 on the target 20, in other words, to scan the surface of the source 20 with the laser beam 34.

FIG. 3 shows the general possibility to combine several shaping devices 60, in this case a size adapting element 64 and a shape adapting element 62. As each of the shaping devices 60 preserves the parallel alignment of the laser beam 34 between the collimation lens 42 and the focusing lens 44, also a combination of two or more shaping devices 60 provides this preservation functionality. The effect of the shape adapting element 62 is depicted by presenting the cross sections 38 of the laser beam 34, whereby the shown shape adapting element 62 alters the cross section 38 of the laser beam 34 from circular to elliptical.

In FIG. 4, a splitting device 46 and its splitting element 48 are shown. In the splitting element 48, the laser beam 34 is split into two partial laser beams 36. Each partial laser beam 36 is independently directed onto the source 20 by the focusing lens 44. Shaping devices 60 (not shown) can also be used to alter parameters as for instance size, shape and/or positon of the partial laser beams 36, both individually and collectively, respectively.

Reference list

| | |
|---|---|
| 10 | laser evaporation system |
| 12 | vacuum chamber |
| 14 | vacuum window |
| 16 | aperture |
| 18 | aperture opening |
| 20 | source |
| 22 | material |
| 30 | laser light source |
| 32 | optical fiber |
| 34 | laser beam |
| 36 | partial laser beam |
| 38 | cross section |
| 40 | laser beam shaping system |
| 42 | collimation lens |
| 44 | focusing lens |
| 46 | splitting device |
| 48 | splitting element |
| 50 | driving apparatus |
| 52 | upstream end |
| 54 | downstream end |
| 60 | shaping device |
| 62 | shape adapting element |
| 64 | size adapting element |
| 66 | position adapting element |

1-24. (canceled)

25. A thermal laser evaporation system, the thermal laser evaporation system comprising:
a laser light source for providing a thermal laser beam for evaporating one or more materials from a source;
a thermal laser beam shaping system comprising a collimation lens and a focusing lens for directing the thermal laser beam onto the source;
a vacuum chamber;
a vacuum window for conducting the thermal laser beam into the vacuum chamber; and
an aperture arranged within the vacuum chamber between the vacuum window and the source,
wherein the thermal laser beam shaping system comprises a shaping device arranged in between the collimation lens and the focusing lens for adapting at least one of a position, a shape, and a size of the thermal laser beam at the source.

26. The thermal laser evaporation system according to claim 25,
wherein the shaping device preserves a parallel or at least essentially parallel alignment of the thermal laser beam after the collimation lens.

27. The thermal laser evaporation system according to claim 25,
wherein the collimation lens and the focusing lens are stationary within the laser beam shaping system.

28. The thermal laser evaporation system according to claim 25,
wherein the shaping device comprises at least some of the following components selected from the group of members consisting of one or more mirrors, one or more beam compressors, one or more beam expanders, one or more beam splitters, one or more lenses, one or more prisms and combinations of the foregoing.

29. The thermal laser evaporation system according to claim 25,
wherein the shaping device comprises one of the following shape adapting elements for adapting the shape of the thermal laser beam:
Anamorphic prism pairs
Combination of cylindrical lenses
Beam clipping elements
Free-form mirrors.

30. The thermal laser evaporation system according to claim 25,
wherein the shaping device comprises one of the following size adapting elements for adapting the size of the thermal laser beam:
A defocusing lens and a matched focusing lens
A focusing lens and a matched defocusing lens
Beam clipping elements
Beam compressors
Beam expanders
Free-form mirrors.

31. The thermal laser evaporation system according to claim 25,
wherein the shaping device comprises one of the following position adapting elements for adapting the position of the thermal laser beam on the source:
Prisms
Mirrors, in particular free-form mirrors
Diffractive optical elements
Beam clipping elements.

32. The thermal laser evaporation system according to claim 31,
wherein the thermal laser beam shaping system comprises a driving apparatus for moving at least one of the position adapting elements for scanning the source by adapting the position of the thermal laser beam on the source.

33. The thermal laser evaporation system according to claim 25,
wherein the thermal laser beam shaping system further comprises a splitting device for splitting the thermal laser beam coming from the laser light source into two or more partial laser beams, wherein the shaping device is configured to adapt at least one of a position, a shape, and a size of the two or more partial laser beams.

34. The thermal laser evaporation system according to claim 32,
wherein the splitting device comprises one of the following splitting elements for splitting the thermal laser beam coming from the laser light source into two or more partial laser beams:
Mirrors
Prisms
Apertures.

35. The thermal laser evaporation system according to claim 33,
wherein the shaping device is configured to adapt the two or more partial laser beams differently with respect to at least one of a position, a shape, and a size of the two or more partial laser beams.

36. The thermal laser evaporation system according to claim 25,
wherein the thermal laser beam is impinging onto the source at an angle between 30° and 60° so that an elliptical beam spot adjusted by the laser beam shaping system directed at the source produces a circular beam spot on the source.

37. The thermal laser evaporation system according to claim 25,
wherein the collimation lens and/or the focusing lens is integrated into the shaping device.

38. The thermal laser evaporation system according to claim 25,
wherein the focusing lens focuses the thermal laser beam on a pointlike focal volume located in the vacuum chamber between the vacuum window and the source, and wherein the aperture comprises an aperture opening and is arranged with its aperture opening at the focal volume for shielding the vacuum window from particles evaporated from the source.

39. A method of providing a thermal laser beam at a source in order to evaporate one or more materials from the source; the method comprising the steps of:
providing a thermal laser beam;
directing the thermal laser beam via a thermal laser beam shaping system comprising a collimation lens, a shaping device and a focusing lens into a vacuum chamber comprising a vacuum window for conducting the thermal laser beam into the vacuum chamber and through an aperture arranged within the vacuum chamber at the source,
wherein the step of directing the thermal laser beam via the thermal laser beam shaping system comprises a configuration of at least one of a position, a shape, and a size of the thermal laser beam at the source by the shaping device.

40. The method according to claim 39,
whereby the method is carried out by a thermal laser evaporation system, the thermal laser evaporation system comprising:
a laser light source for providing the thermal laser beam for evaporating one or more materials from the source;
the thermal laser beam shaping system comprising a collimation lens and a focusing lens for directing the thermal laser beam onto the source;
the vacuum chamber;
the vacuum window for conducting the thermal laser beam into the vacuum chamber; and
the aperture arranged within the vacuum chamber between the vacuum window and the source,
wherein the thermal laser beam shaping system comprises a shaping device arranged in between the collimation lens and the focusing lens for adapting at least one of a position, a shape, and a size of the thermal laser beam at the source.

41. The method according to claim 39,
whereby a parallel or at least essential parallel alignment of the thermal laser beam after the collimation lens is preserved by the shaping device.

42. The method according to claim 39,
whereby the shape of the thermal laser beam is adapted by clipping parts of the thermal laser beam and/or by using anamorphic prism pairs and/or a combination of cylindrical lenses and/or free-form mirrors for altering the shape of the thermal laser beam.

43. The method according to claim 42,
whereby a thermal laser beam provided by the laser light source with circular cross section is transformed by the shaping device into a thermal laser beam with an elliptical cross section.

44. The method according to claim 39,
whereby the size of the thermal laser beam is adapted by clipping parts of the thermal laser beam and/or by using a matched pair of a defocusing lens and a focusing lens and/or beam compressors and/or beam expanders and/or free-form mirrors.

45. The method according to claim 39,
whereby the position of the thermal laser beam on the source is adapted by clipping parts of the thermal laser beam and/or by using position adapting elements, in particular mirrors and/or prisms and/or diffractive optical elements, for altering the position of the thermal laser beam within the beam shaping system.

46. The method according to claim 45,
whereby adapting the position of the thermal laser beam includes scanning the laser beam across the source by moving at least one of the position adapting elements by a driving apparatus of the thermal laser beam shaping system.

47. The method according to claim 39,
whereby the step of directing the thermal laser beam via the thermal laser beam shaping system comprises splitting the thermal laser beam coming from the laser light source into two or more partial laser beams by a splitting device of the thermal laser beam shaping system.

48. The method according to claim 39,
wherein the thermal laser beam shaping system focuses the thermal laser beam on a pointlike focal volume located in the vacuum chamber between the vacuum window and the source, and wherein an aperture is arranged with its aperture opening at the focal volume and shields the vacuum window from particles evaporated from the source.
